(19) United States
(12) Patent Application Publication
(10) Pub. No.: US 2009/0179211 A1
(43) Pub. Date: Jul. 16, 2009

(54) Light emitting device

(76) Inventors: Tae-Kyung Yoo, Kyunggi-do (KR); Chang-Tae Kim, Kyunggi-do (KR); Keuk Kim, Kyunggi-do (KR)

Correspondence Address: HARNESS, DICKEY, & PIERCE, P.L.C, 7700 Bonhomme, Suite 400, ST. LOUIS, MO, 63105, US

(21) Appl. No.: 11/988,882

(22) PCT Filed: Jul. 14, 2006
(86) PCT No.: PCT/KR2006/002790

§ 371 Date: Feb. 5, 2009

(30) Foreign Application Priority Data
Jul. 14, 2005 (KR) 10-2005-0063864
Jul. 14, 2005 (KR) 10-2005-0063912
Aug. 25, 2005 (KR) 10-2005-0078508
Aug. 26, 2005 (KR) 10-2005-0078848
Aug. 27, 2005 (KR) 10-2005-0079108

(51) Int. Cl. H01L 33/00

(52) U.S. Cl. 257/98; 257/103; 257/79; 257/E33.074; 257/E33.023

(57) ABSTRACT

The present invention discloses a semiconductor light emitting device including an active layer for generating light by recombination of electron and hole between a first semiconductor layer having first conductivity and a second semiconductor layer having second conductivity different from the first conductivity, the second semiconductor layer being disposed on the active layer. The semiconductor light emitting device comprises first array including a trench having a first inclination angle, and second array including a trench having a second inclination angle different from the first inclination angle.

### TECHNICAL FIELD

The present invention relates to a semiconductor light emitting device, and more particularly, to a semiconductor light emitting device which can restrict inside heat generation and improve external quantum efficiency. The semiconductor light emitting device means a semiconductor device which emits light by using recombination of electron and hole, for example, a III-nitride semiconductor light emitting device.

### BACKGROUND ART

FIGS. 1 and 2 are a cross-sectional view and a plane view illustrating one example of a conventional semiconductor light emitting device, namely, a III-nitride semi-conductor light emitting device. The conventional semiconductor light emitting device includes a substrate 1, a buffer layer 2 epitaxially grown on the substrate 1, an n-type nitride semiconductor layer 3 epitaxially grown on the buffer layer 2, an active layer 4 epitaxially grown on the n-type nitride semiconductor layer 3, a p-type nitride semi-conductor layer 5 epitaxially grown on the active layer 4, a p-side electrode 6 formed on the p-type nitride semiconductor layer 5, a p-side bonding pad 7 formed on the p-side electrode 6, and an n-side electrode 8 formed on the n-type nitride semiconductor layer 31 exposed by mesa-etching the p-type nitride semiconductor layer 5 and the active layer 4. The semiconductor light emitting device serves as a light emitting device by generating light on the active layer 4 by recombination of electron and hole and externally emitting the light.

The more the light generated on the active layer 4 is externally emitted from the light emitting device, the more efficiency of the light emitting device (external quantum efficiency) is improved. However, some of the light is confined in the light emitting device and vanished as heat due to a difference in a refractive index between materials composing the light emitting device and the outside (air). U.S. Pat. No. 3,739,217, Japan Laid-Open Patent H06-291368 and U.S. Pat. No. 5,429,954 have been disclosed to solve the foregoing problem. As illustrated in FIG. 3, a light emitting device has a rough surface, for increasing a probability of externally emitting light generated on an active layer 4 from the light emitting device.

FIG. 4 is a plane view illustrating another example of the conventional semi-conductor light emitting device. A rough surface 1000 is formed on the sides of the light emitting device, for efficiently externally extracting light moving to the sides of the light emitting device from the light emitting device (Japan Laid-Open Patent 2003-110136).

FIG. 5 is a cross-sectional view illustrating yet another example of the conventional semiconductor light emitting device. In the 111-nitride semiconductor light emitting device, a plurality of trenches 9 are formed by removing a p-type nitride semi-conductor layer 5, an active layer 4 and part of an n-type nitride semiconductor layer 3. Light 91 moving to the sides of the device is extracted through the trenches 9, thereby improving external quantum efficiency of the device. Japan Laid-Open Patents 2002-026386 and 2002-164574 disclose a technique of applying the trenches to the III-nitride semiconductor light emitting device. Japan Laid-Open Patent S50-105286 discloses a technique of applying the trenches to a general semiconductor light emitting device having a p-n junction structure.

FIG. 6 is a plane view illustrating yet another example of the conventional semi-conductor light emitting device. An electric field 2000 is formed between a p-side bonding pad 7 and an n-side electrode 8. A trench 9 for current blocking is formed at the center of the light emitting device, for preventing the electric field 2000 from being concentrated on the center of the light emitting device, and evenly generating the electric field 2000 on the whole light emitting device (U.S. Pat. No. 6,781,147).

FIG. 7 is a cross-sectional view illustrating one example of a conventional high output nitride semiconductor light emitting device. The high output nitride semi-conductor light emitting device includes a substrate 100, a buffer layer 200 epitaxially grown on the substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a light transmitting electrode 600 formed almost on the entire surface of the p-type nitride semiconductor layer 500, a p-side electrode 700 formed on the light transmitting electrode 600, and an n-side electrode 800 formed on the n-type nitride semiconductor layer 301 exposed by mesa-etching at least the p-type nitride semiconductor layer 500 and the active layer 400. In addition, a metal film 900 is formed on the bottom surface of the substrate 100, for facilitating heat emission of the high output device.

FIG. 8 is a plane view illustrating the high output light emitting device of FIG. 7. In order to embody the high output light emitting device having a large size and a few hundreds mA of driving current, the p-side electrode 700 having a plurality of arms 711, 712, 713 and 714 is formed on the light transmitting electrode 600, and the n-side electrode 800 having a plurality of arms 611, 612 and 613 is formed on the surface 301 exposed by mesa-etching. Here, the electrodes 700 and 800 are interdigitated with predetermined intervals between the arms 711, 712, 713 and 714 and the arms 611, 612 and 613, thereby maintaining a current density as constant as possible. In the conventional high output nitride semiconductor light emitting device, the current flowing into the p-type nitride semiconductor layer 500 passes through the active layer 400 and flows into the n-type nitride semiconductor layer 300 to generate heat. Since the heat generated at the center of the device is not easily externally emitted from the device, the center of the device has a higher temperature than the edges of the device. As a result, the heat is intensively generated at the center of the device, which seriously reduces reliability and efficiency of the device.

### DISCLOSURE OF INVENTION

### 1. Technical Problem

The present invention is achieved to solve the above problems. An object of the present invention is to provide a semiconductor light emitting device having a new structure which can externally emit more light generated on an active layer.

Another object of the present invention is to provide a semiconductor light emitting device which can improve external quantum efficiency without blocking current.

Yet another object of the present invention is to provide a III-nitride semiconductor light emitting device having the aforementioned structure.

Yet another object of the present invention is to provide a semiconductor light emitting device which can improve external quantum efficiency by using trenches.

Yet another object of the present invention is to provide a semiconductor light emitting device which can form a structure of improving external quantum efficiency without requiring an additional process.

Yet another object of the present invention is to provide a semiconductor light emitting device which can efficiently restrict inside heat generation.

Yet another object of the present invention is to provide a semiconductor light emitting device which can improve external quantum efficiency by forming a trench and minimize current blocking of the trench.

Yet another object of the present invention is to improve performance and re-liability of the high output nitride semiconductor light emitting device through reducing heat generation inside the high output nitride semiconductor light emitting device by restricting current flows to the center of the device by removing an electrode or a semiconductor layer from the center of the device.

### Technical Solution

In order to achieve the above-described objects of the invention, there is provided a semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising a first array including a trench having a first inclination angle, and a second array including a trench having a second inclination angle different from the first inclination angle. Here, the trenches of the arrays need not to be formed in the same shape, angle and size.

Preferably, the first and second arrays are disposed so that a current flow can be formed in a zigzag shape therebetween. This structure improves external quantum efficiency by the trenches and facilitates current flows.

Preferably, the first and second arrays do not overlap with each other. This structure facilitates current flows.

Preferably, the trench having the first inclination angle has a first length in a first direction and a second length in a second direction perpendicular to the first direction, and the first length is longer than the second length. Therefore, the trench can be formed in various shapes except circle, for guiding current flows and extracting light.

Preferably, a difference between the first inclination angle and the second inclination angle is larger than a critical angle of a semiconductor material composing the semiconductor light emitting device and an external material. The angle difference is not limited, but preferably, is larger than the critical angle, for increasing a probability of emitting light generated on the active layer through the trench.

Preferably, a difference between the first inclination angle and the second inclination angle is 90. This structure is a good example of a compromise between first and second characteristics of the present invention discussed later.

Preferably, the trench having the first inclination angle includes a rough surface.

Preferably, a sidewall of the trench having the first inclination angle is inclined.

According to another aspect of the present invention, there is provided a semi-conductor light emitting device including an active layer for generating light by re-combination of electron and hole between a first semiconductor layer having a first conductivity and a second semiconductor layer having a second conductivity different from the first conductivity, the second semiconductor layer being disposed on the active layer, comprising a trench having a first length in a first direction and a second length in a second direction perpendicular to the first direction, the first length being longer than the second length, the second direction being inclined to one side of the semiconductor light emitting device. Generally, the semiconductor light emitting device has a rectangular cross-section. If one of the lines (boundaries of the light emitting device and the outside) composing the cross-section is set as a basis, the trench is inclined to the basis. The boundary of the light emitting device and the outside also serves as an extraction surface of light generated on the active layer (it can be regarded as a kind of trench). The trench is formed in an angle different from the angle of the boundary, for increasing a probability of extracting light.

According to yet another aspect of the present invention, there is provided a semi-conductor light emitting device including an active layer for generating light by re-combination of electron and hole between a first semiconductor layer having a first conductivity and a second semiconductor layer having a second conductivity different from the first conductivity, the second semiconductor layer being disposed on the active layer, comprising an array including a plurality of trenches having a first length in a first direction and a second length in a second direction perpendicular to the first direction, the first length being longer than the second length, the second direction being inclined to one side of the semiconductor light emitting device.

According to yet another aspect of the present invention, there is provided a semi-conductor light emitting device including an active layer for generating light by re-combination of electron and hole between a first semiconductor layer having first conductivity and a second semiconductor layer having second conductivity different from the first conductivity, the second semiconductor layer being disposed on the active layer, comprising a first array including a first trench and a second array including a second trench, the first and the second arrays being disposed so that a current flow can be formed in a zigzag shape therebetween. Here, the present invention is understood in the viewpoint of arrangement of the arrays including the trenches.

According to yet another aspect of the present invention, there is provided a semi-conductor light emitting device including an active layer for generating light by re-combination of electron and hole between a first semiconductor layer having a first conductivity and a second semiconductor layer having a second conductivity different from the first conductivity, the second semiconductor layer being disposed on the active layer, a first array including a first trench and a second array including a second trench, the first and second trenches being disposed so that a current flow between the first and second arrays can be formed in a zigzag shape. The present invention is understood in the viewpoint of arrangement of the trenches.

According to yet another aspect of the present invention, there is provided a semi-conductor light emitting device including an active layer for generating light by re-combination of electron and hole between a first semiconductor layer having a first conductivity and a second semiconductor layer having a second conductivity different from the first conductivity, the second semiconductor layer being disposed on the active layer, comprising a trench formed by removing the structure from the region of the second semiconductor layer at least to the active layer, the trench having a surface for externally emitting some of incident light from the device, scattering the other incident light from the device back into the device, and guiding current flows in a zigzag shape in the device. The present invention is understood in the viewpoint of functions of the trench for emitting and scattering light and guiding current flows. Here, the surface of the trench can be rough surfaces. The trenches can be designed with a margin in number and arrangement.

According to yet another aspect of the present invention, there is provided a semi-conductor light emitting device including an active layer for generating light by re-combination of electron and hole between a first semiconductor layer having a first conductivity and a second semiconductor layer having a second conductivity different from the first conductivity, the second semiconductor layer being disposed on the active layer, comprising a plurality of trenches having a first length in a first direction and a second length in a second direction perpendicular to the first direction, the first length being longer than the second length, and a light emitting point for omnidirectionally emitting light from the surface parallel to the active layer, wherein the plurality of trenches are arranged to meet the whole light omnidirectionally emitted from the light emitting point. Here, the present invention is understood in the viewpoint of the first characteristic discussed later.

According to yet another aspect of the present invention, there is provided a semi-conductor light emitting device including a plurality of semiconductor layers having an active layer for generating light by recombination of electron and hole, the plurality of semiconductor layers being comprised of a first semiconductor layer being positioned under the active layer and having first conductivity and a second semiconductor layer being positioned over the active layer and having second conductivity different from the first conductivity, comprising a trench formed in the plurality of semiconductor layers by removing at least the second semiconductor layer and the active layer, and a protrusion formed on the bottom surface of the trench for scattering light generated on the active layer. In accordance with the present invention, the trench is formed to more efficiently externally emit light from the device, and the protrusion is formed on the bottom surface of the trench, namely, the removed light emitting region to externally emit more light from the device.

Preferably, the side of the trench is inclined surface. Therefore, the area of externally emitting light is enlarged to improve external quantum efficiency.

Preferably, the first semiconductor layer and the second semiconductor layer are comprised of AlₓGa_{y}In_{1-x-y}N (0≦x≦1, 0≦y≦1, 0≦x+y≦1). It implies that the present invention can be applied to a III-nitride semiconductor light emitting device.

Preferably, the trench comprises a center trench positioned at the center of the device for restricting heat generation of the device. Recently, the area of the semi-conductor light emitting device increases, which causes problems in restriction of heat generation or radiation. Formation of the center trench is one of the preferable embodiments of the present invention in the large area tendency of the device.

Preferably, the substrate is an insulative or conductive substrate. Generally, a sapphire substrate is used as the insulative substrate, and GaAs substrate, SiC substrate or the like is used as the conductive substrate. However, any kind of substrate on which the semiconductor layer can be grown can be used.

Preferably, a process for removing the plurality of semiconductor layers to form the trench, the protrusion and the first electrode is carried out by using one mask pattern. The plurality of semiconductor layers can be removed by dry or wet etching. The present invention can provide the semiconductor light emitting device which can improve external quantum efficiency by forming the trench and the protrusion in the conventional process for forming the electrode without requiring an additional process (it can be easily performed by removing the plurality of semiconductor layers by adding a pattern for forming the trenches and the protrusions to a mask pattern used in the conventional process for forming the electrode).

Preferably, the trench is formed in an electric field direction to prevent the current flow from being blocked. Accordingly, the trenches are distinguished from the general trenches for blocking the current. Since the trench is formed in the electric field direction, external quantum efficiency can be improved without blocking the current.

According to yet another aspect of the present invention, there is provided a semi-conductor light emitting device including a substrate, and a plurality of nitride semi-conductor layers grown over the substrate, the plurality of nitride semiconductor layers having a first nitride semiconductor layer electrically contacting a first electrode, a second nitride semiconductor layer electrically contacting a second electrode, and an active layer positioned between the first nitride semiconductor layer and the second nitride semiconductor layer, for generating light by recombination of electron and hole, comprising a temperature rise restricting area being formed at the center of the device.

Preferably, the temperature rise restricting area is formed by removing the second electrode at the center of the device. The second electrode disposed at the center of the device can be removed by not depositing a second electrode material on the center of the device in a process for depositing the second electrode, or by removing the second electrode after deposition.

Preferably, the temperature rise restricting area is formed by removing the structure at least to the active layer at the center of the device. More preferably, the first nitride semiconductor layer is partially removed.

Preferably, temperature rise restricting area includes a protrusion at the bottom surface of the removed temperature rise restricting area. The protrusion is used to restrict heat generation at the center of the device, and the removed part is used to improve external quantum efficiency.

In accordance with the present invention, external quantum efficiency of the device can be improved without blocking current.

In accordance with the present invention, the III-nitride semiconductor light emitting device can be embodied to improve external quantum efficiency without blocking current.

In accordance with the present invention, the large area semiconductor light emitting device can be embodied to improve external quantum efficiency without blocking current.

In accordance with the present invention, external quantum efficiency of the semi-conductor light emitting device can be more improved by forming the trench having the protrusion on their bottom surface.

In accordance with the present invention, external quantum efficiency of the semi-conductor light emitting device is improved without requiring an additional process, by performing the process for forming the trench having the protrusion on their bottom surface and the process for forming the electrode together.

In accordance with the present invention, heat generation of the semiconductor light emitting device can be efficiently restricted by removing part of the light emitting region of the device, furthermore, the center part of the device.

In accordance with the present invention, external quantum efficiency can be improved, and blocking of current by the trenches can be minimized.

In accordance with the present invention, performance and reliability of the high output semiconductor light emitting device are improved by restricting or preventing heat generation in the device by restricting current flows to the center of the device.

### BRIEF DESCRIPTION OF THE DRAWINGS

The present invention will become better understood with reference to the accompanying drawings which are given only by way of illustration and thus are not limitative of the present invention, wherein:

FIG. 1 is a cross-sectional view illustrating one example of a conventional semi-conductor light emitting device;

FIG. 2 is a plane view illustrating the conventional semiconductor light emitting device of FIG. 1;

FIG. 3 is a side view illustrating another example of the conventional semiconductor light emitting device;

FIG. 4 is a plane view illustrating yet another example of the conventional semi-conductor light emitting device;

FIG. 5 is a cross-sectional view illustrating yet another example of the conventional semiconductor light emitting device;

FIG. 6 is a plane view illustrating yet another example of the conventional semi-conductor light emitting device;

FIG. 7 is a cross-sectional view illustrating one example of a conventional high output nitride semiconductor light emitting device;

FIG. 8 is a plane view illustrating the conventional high output nitride semi-conductor light emitting device of FIG. 7;

FIG. 9 is a plane view illustrating a semiconductor light emitting device in accordance with one embodiment of the present invention;

FIG. 10 is a schematic cross-sectional view taken along line A-B of FIG. 9;

FIG. 11 is a view showing a principle of a first characteristic of the present invention;

FIG. 12 is a view showing an example of forming trench patterns in the light emitting device in the viewpoint of the first characteristic of the present invention;

FIG. 13 is a view showing a principle of a second characteristic of the present invention;

FIG. 14 is a cross-sectional view illustrating a semiconductor light emitting device in accordance with another embodiment of the present invention;

FIG. 15 is a schematic view illustrating a semiconductor light emitting device on which a trench is formed;

FIG. 16 is a schematic view illustrating a semiconductor light emitting device in which protrusions are formed on a bottom surface of a trench;

FIG. 17 is a schematic view illustrating a semiconductor light emitting device on which a trench having an inclined sidewall is formed;

FIG. 18 is a schematic view illustrating a semiconductor light emitting device in which a sidewall of a trench is inclined and protrusions are formed on the bottom surface of the trench;

FIG. 19 is a schematic view illustrating a semiconductor light emitting device in which a plurality of trenches are formed;

FIG. 20 is a plane view illustrating a semiconductor light emitting device in accordance with the present invention;

FIG. 21 is a cross-sectional view taken along line A-A′ of FIG. 20;

FIG. 22 is a plane view illustrating a semiconductor light emitting device in accordance with yet another embodiment of the present invention;

FIG. 23 is a cross-sectional view taken along line B-B′ of FIG. 22;

FIG. 24 is a plane view illustrating a semiconductor light emitting device in accordance with yet another embodiment of the present invention;

FIG. 25 is a cross-sectional view taken along line C-C′ of FIG. 24;

FIG. 26 is a view showing a principle of the present invention;

FIGS. 27 to 29 are views illustrating examples of a III-nitride semiconductor light emitting device in accordance with the present invention;

FIG. 30 is a view illustrating another example of the III-nitride semiconductor light emitting device in accordance with the present invention;

FIG. 31 is a cross-sectional view taken along line A-A′ of FIG. 30;

FIG. 32 is another cross-sectional view taken along line A-A′ of FIG. 30; and

FIGS. 33 and 34 are a plane view and a cross-sectional view illustrating yet another example of the III-nitride semiconductor light emitting device in accordance with the present invention.

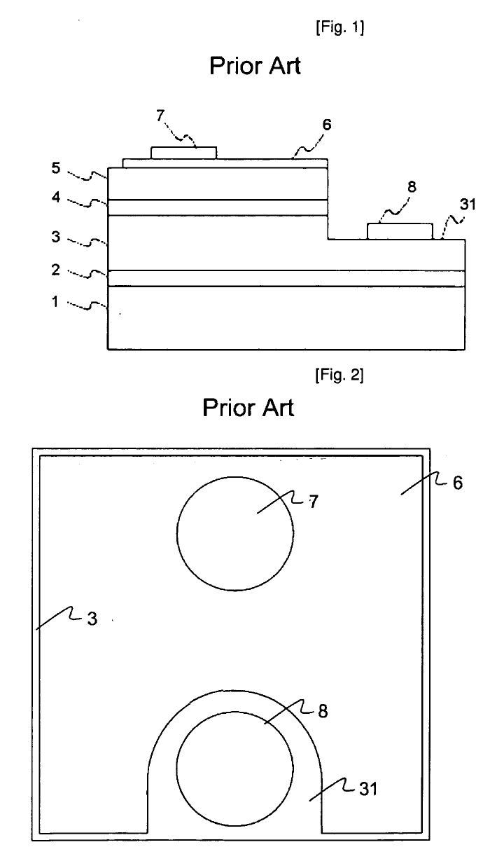

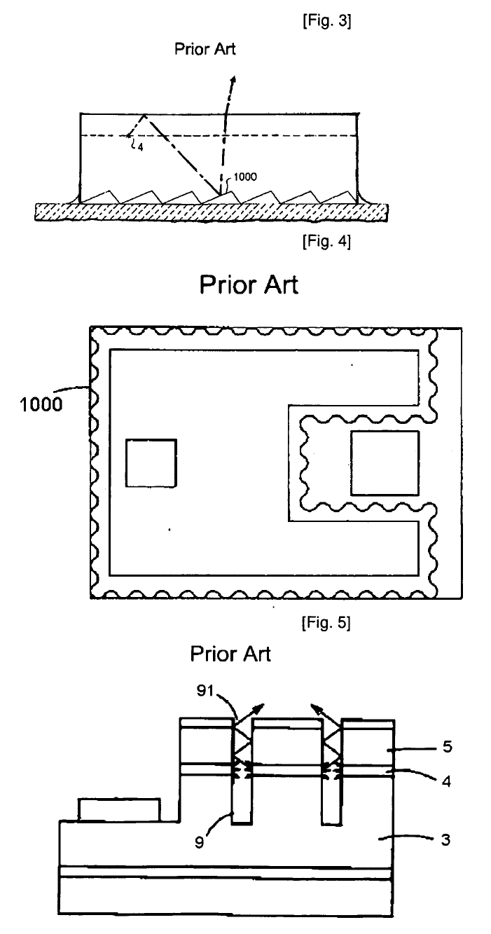

### MODE FOR THE INVENTION

A light emitting device in accordance with preferred embodiments of the present invention will now be described in detail with reference to the accompanying drawings.

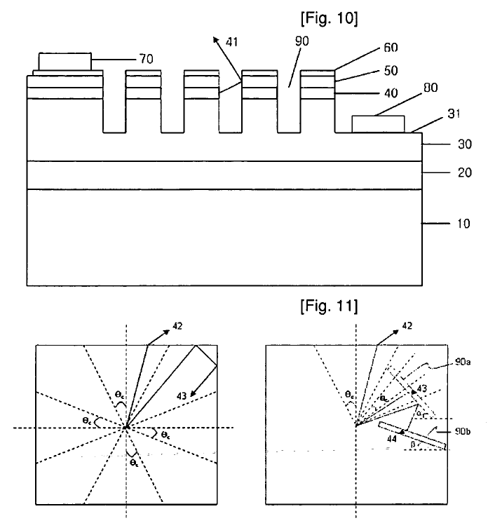

FIG. 9 is a plane view illustrating a semiconductor light emitting device in accordance with one embodiment of the present invention, and FIG. 10 is a schematic cross-sectional view taken along line A-B of FIG. 9. Here, the present invention is applied to a III-nitride semiconductor light emitting device. The light emitting device includes a substrate 10, a buffer layer 20 epitaxially grown on the substrate 10, an n-type nitride semiconductor layer 30 epitaxially grown on the buffer layer 20, an active layer 40 epitaxially grown on the n-type nitride semiconductor layer 30, a p-type nitride semiconductor layer 50 epitaxially grown on the active layer 40, a p-side electrode 60 formed on the p-type nitride semiconductor layer 50, a p-side bonding pad 70 formed on the p-side electrode 60, and an n-side electrode 80 formed on the n-type nitride semiconductor layer 31 exposed by mesa-etching the p-type nitride semi-conductor layer 50 and the active layer 40. Trenches 90 are formed on the top surface of the light emitting device by removing the p-side electrode 60, the p-type nitride semiconductor layer 50, the active layer 40 and part of the n-type nitride semi-conductor layer 30. Light 41 moving to the sides of the light emitting device is externally emitted from the device through the trench 90, thereby improving efficiency of the device.

In accordance with a first characteristic of the present invention, the light emitting device includes a trench having an inclination angle, preferably, at least two or more trenches having different inclination angles, thereby extracting more light through the trenches.

FIG. 11 is a view showing a principle of the first characteristic of the present invention. As shown in the left side of FIG. 11, when the light emitting device has a rectangular cross-section, light 42 can be externally extracted from the device, and light 43 can not be extracted and be vanished in the device. When light is incident within a critical angle q_{c} to the boundary of the device and the outside (for reference, a critical angle of nitride semiconductor GaN to the air ranges from 23° to 24°, it can be externally extracted from the device. The light 43 incident outside the critical angle θ_{c} can not be externally emitted from the device and be vanished as heat. However, as shown in the right side of FIG. 11, when the light emitting device includes a trench 90a having an inclination angle α, the light 43 incident outside the critical angle θ_{c} is externally emitted from the device through the trench 90a having the inclination angle α. Furthermore, the light emitting device additionally includes a trench 90b having an inclination angle β different from the inclination angle α of the trench 90a. Light 44 incident outside a critical angle to the trench 90a having the inclination angle α is externally emitted from the device through the trench 90b having the inclination angle β. Accordingly, a probability of externally emitting light from the device increases.

In addition, since the trench 90b having the inclination angle β is formed adjacently to the trench 90a having the inclination angle α, a path of light can be changed to increase a probability of externally emitting light from the device, and a movement path of light can be shortened to decrease a probability of vanishing light as heat in the device.

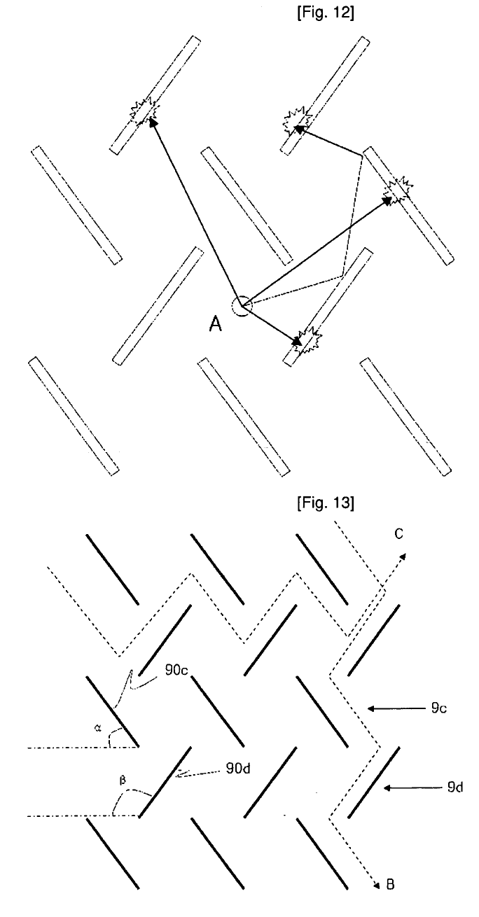

FIG. 12 is a view showing an example of forming a pattern of trenches in the light emitting device in the viewpoint of the first characteristic of the present invention. A plurality of trenches having different inclination angles are arranged to surround a light emitting point A. Most of light generated from the light emitting point A is externally emitted from the device through a short path.

A second characteristic of the present invention is reducing current blocking of the trenches, with increasing the amount of light extracted through the trenches.

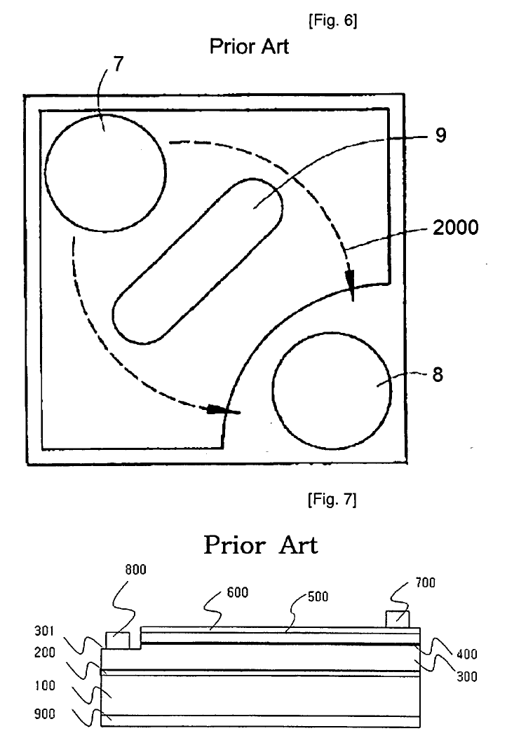

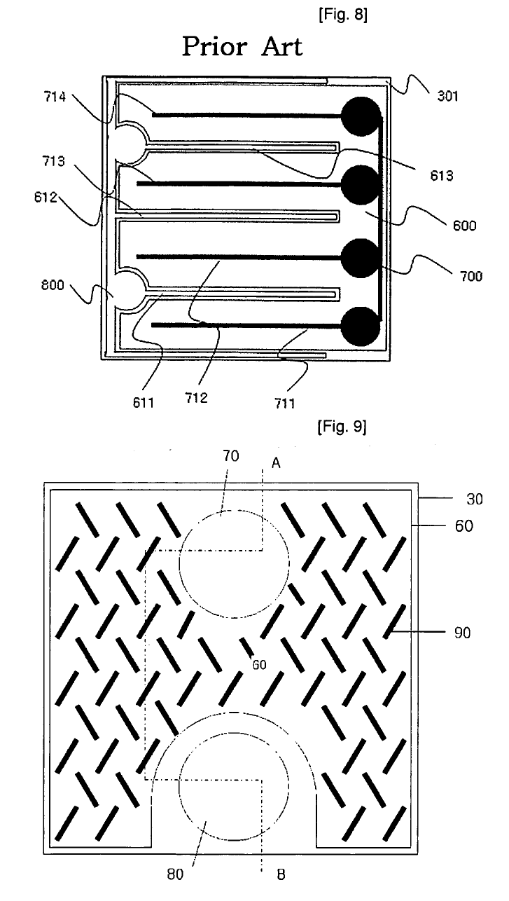

In the conventional semiconductor light emitting device, the trenches are formed to improve external quantum efficiency. Such trenches block the current and increase the current density in the device. Moreover, the conventional semiconductor light emitting device of FIG. 6 uses the trench as a means for current blocking.

The second characteristic of the present invention is related to forming the trenches to improve external quantum efficiency, and arranging the trenches not to block the current.

FIG. 13 is a view showing a principle of the second characteristic of the present invention. Array 9c including trenches 90c having an inclination angle α and array 9d including trenches 90d having an inclination angle β are sequentially arranged. Current B and C flow in a zigzag shape between the plurality of discontinuous trenches 90c and 90d without serious blocking.

Because the first and second characteristics of the present invention are contradictory to each other (namely, forming a plurality of trenches having different inclination angles is preferable to improve external quantum efficiency, but not preferable to facilitate current flows), they must be appropriately reflected. For example, the inclination angle α of the trenches 90c is set to 45° and the inclination angle β of the trenches 90d is set to 135° so that the trenches 90c and the trenches 90d can be disposed at an angle of 90° In order to facilitate the perpendicular direction current flow B and the horizontal direction current flow C, the array 9c including the trenches 90c and the array 9d including the trenches 90d are disposed not to overlap with each other.

The size of the trenches 90c and 90d is not limited but varied with the size of the light emitting device. Preferably, the width and length of the trenches 90c and 90d range from 10 nm to 1000□. If the width of the trenches 90c and 90d is too narrow, the trenches 90c and 90d can not function, and if the width of the trenches 90c and 90d is too wide, the trenches 90c and 90d restrict the light emitting area of the device and disturb the function of the device.

The interval between the trenches 90c and 90d is not limited either. Preferably, the interval is set over 10 nm. If the interval between the trenches 90c and 90d is too narrow, the trenches 90c and 90d excessively increase the current density and block the current.

The shape of the trenches 90c and 90d is not limited to the rectangle. The trenches 90c and 90d can be formed in various shapes to guide current and extract light.

On the other hand, the trenches 90c and 90d can be formed by dry etching such as induction coupled plasma (ICP).

In addition, the trenches 90c and 90d only have to be formed by removing the structure at least to the active layer, and the depth of downwardly removing the structure is not limited.

An insulator such as epoxy can be partially or entirely filled in the trenches 90c and 90d for insulation.

Rough surfaces applied to the conventional light emitting device can be formed on the trenches 90c and 90d. This structure does not simply add the prior art to the technique of forming the trenches 90c and 90d, but variously changes the path of light incident on the trenches 90c and 90d. Therefore, the number of the trenches 90c and 90d can be changed or the inclination angles can be set with a margin, thereby designing the device with smooth current flows. The rough surfaces can be formed on the sides and bottoms of the trenches 90c and 90d, and can be easily formed by etching.

The sidewalls of the trenches 90c and 90d can be inclined. As compared with the perpendicular surfaces, the inclined sidewalls can enlarge the light extracting area.

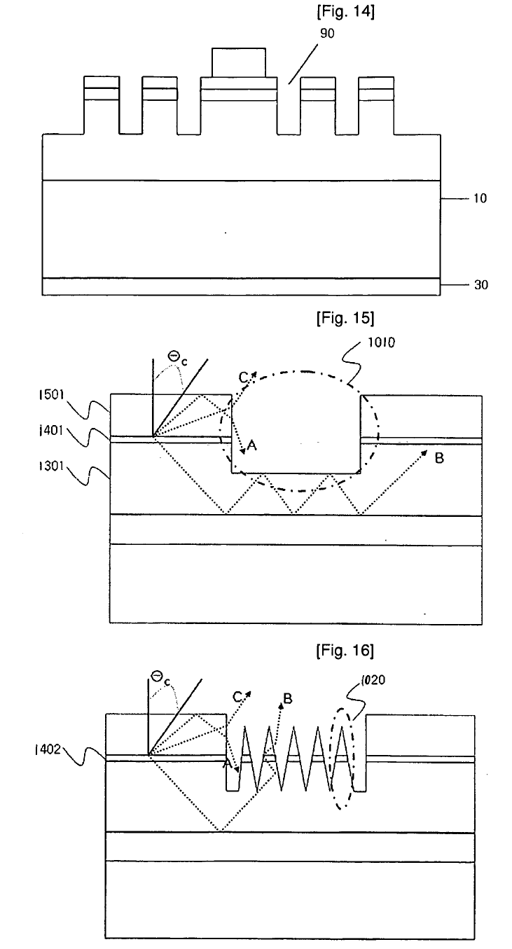

FIG. 14 is a cross-sectional view illustrating a semiconductor light emitting device in accordance with another embodiment of the present invention. The trenches 90 are applied to a conductive substrate such as SiC substrate. The semiconductor light emitting device is different from the above-described device merely in that the n-side electrode 30 is positioned under the substrate 10.

FIG. 15 is a schematic view illustrating a semiconductor light emitting device on which a trench is formed. The trench 1010 is formed by removing a p-type semi-conductor layer 1501, an active layer 1401 and part of an n-type semiconductor layer 1301. Among the light A, B and C generated on the active layer 1401, most of the light having a larger incident angle than an escape angle θ_{c} is externally emitted through the trench 1010. The area of the trench 1010 depends on the size of the device, generally, ranges from 1□² to 1 mm².

FIG. 16 is a schematic view illustrating a semiconductor light emitting device in which a protrusion is formed on a bottom surface of a trench. The light emitting device can more efficiently extract light A, B and C generated on an active layer 1402. The protrusion 1020 can be formed in a horn or hemisphere shape, and the section of the bottom of the protrusion 1020 can be formed in various shapes such as circle, triangle, tetragon and hexagon. The area of the bottoms of the protrusion 1020 ranges from 1□² to 10□², and the height of the protrusion 1020 ranges from 1 nm to 10 mm.

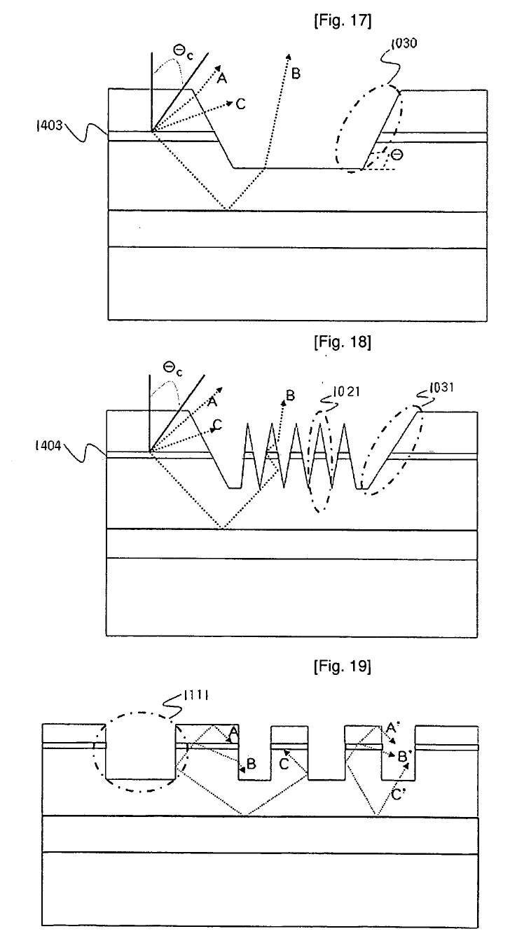

FIG. 17 is a schematic view illustrating a semiconductor light emitting device on which a trench having an inclined sidewall is formed. As the sidewall 1030 is inclined, light A, B and C generated on an active layer 1403 can be more efficiently extracted. An inclination angle θ of the inclined surface 1030 is smaller than 90° preferably, ranges from 45° to 55°.

FIG. 18 is a schematic view illustrating a semiconductor light emitting device in which a sidewall of a trench is inclined and a protrusion is formed on the bottom surface of the trench. As the inclined surface 1031 and the protrusion 1021 are formed, light generated on an active layer 1404 can be most efficiently extracted to improve external quantum efficiency.

FIG. 19 is a schematic view illustrating a semiconductor light emitting device in which a plurality of trenches are formed. When the trenches 1111 are provided in the plural number and intervals between the trenches 1111 are narrow, external quantum efficiency is more improved.

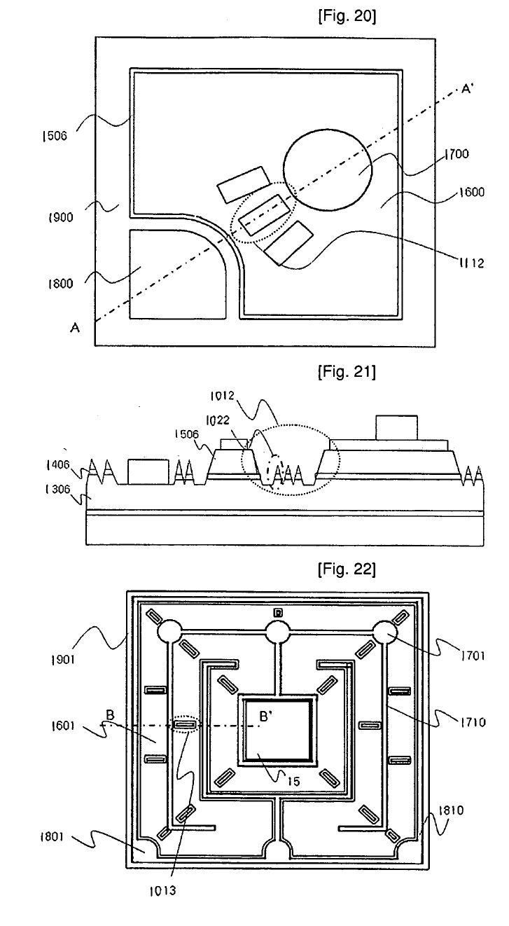

FIG. 20 is a plane view illustrating a semiconductor light emitting device in accordance with the present invention. A light transmitting electrode 1600 is formed on a p-type semiconductor layer 1506, a p-side bonding pad 1700 is formed on the light transmitting electrode 1600, and an n-side electrode 1800 is formed on an exposed n-type semiconductor layer 1900.

A trench 1012 is formed between the p-side bonding pad 1700 and the n-side electrode 1800, not to block current, preferably, in the same direction as a direction of an electric field. The direction of the electric field can be changed by the positions of the p-side bonding pad 1700 and the n-side electrode 1800. The trench 1012 is disposed according to the electrode arrangement.

FIG. 21 is a cross-sectional view taken along line A-A′ of FIG. 20. Protrusion 1022 is formed on the region exposed by etching the p-type semiconductor layer 1506, an active layer 1406 and an n-type semiconductor layer 1306 as well as the bottom surface of the trench 1012.

A general semiconductor light emitting device consumes 60 to 100 mW of power. Here, a driving current is about 20 mA, and a current density of the device is about 50 A/cm². In the present invention, the trench 1012 is formed by removing part of the semiconductor layer including the active layer 1406. As the number of the trenches 1012 increases, the current density of the device also increases. Excessive increase of the current density is not good for the operation of the device. Preferably, the trenches 1012 are designed to increase the current density below 50%.

FIG. 22 is a plane view illustrating a semiconductor light emitting device in accordance with yet another embodiment of the present invention. The device has a different electrode structure from that of FIG. 20. A plurality of p-side bonding pads 1701 and a plurality of arm electrodes 1710 for connecting the p-side bonding pads 1701 are formed on a light transmitting electrode 1601, and a plurality of n-side electrodes 1801 and a plurality of arm electrodes 1810 for connecting the n-side electrodes 1801 are formed on an exposed n-type semiconductor layer 1901. Trenches 1013 are formed between the electrodes not to block current.

A center trench 15 is formed at the center of the device. The center trench 15 is intended to improve light emitting efficiency of the device by restricting heat generation by removing the center portion on which heat is concentrated. The area of the center trench 15 is varied by the whole size of the device, preferably, decided between 10□² band 1 mm². When the area of the center trench 15 is below 10□², heat generated in the device is not efficiently removed, and thus the lifespan of the device may be reduced. When the area of the center trench 15 is over 1 mm², a light emitting area of the device is reduced, and thus light emitting efficiency thereof may be reduced.

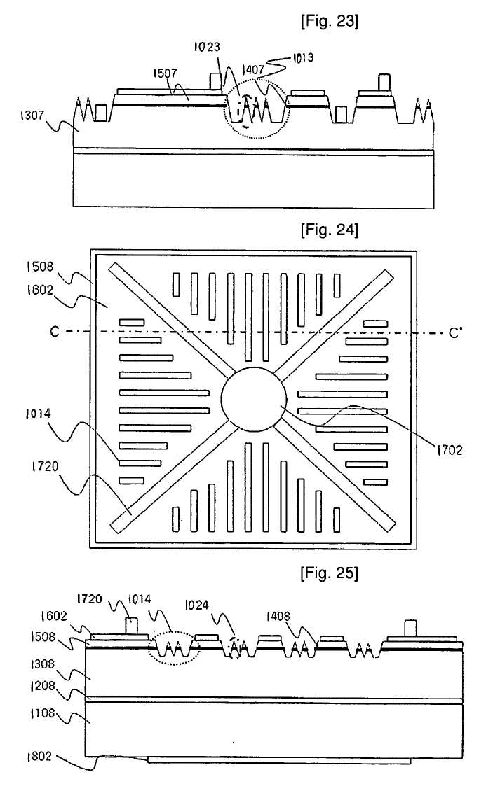

FIG. 23 is a cross-sectional view taken along line B-B′ of FIG. 22. Protrusion 1023 is formed on the region exposed by etching a p-type semiconductor layer 1507, an active layer 1407 and an n-type semiconductor layer 1307 as well as the bottom surfaces of trenches 1013.

Identically to the semiconductor light emitting device of FIG. 20, in the semi-conductor light emitting device of FIG. 22, the trenches 1013 are designed to increase a current density below 50%.

FIG. 24 is a plane view illustrating a semiconductor light emitting device in accordance with yet another embodiment of the present invention. Here, trenches 1014 are applied to a conductive substrate. Since an n-side electrode 1802 is positioned under the substrate 1108, a light transmitting electrode 1602, a p-side bonding pad 1702 and arm electrodes 1720 extended from the p-side bonding pad 1702 are formed on a p-type semiconductor layer 1508.

FIG. 25 is a cross-sectional view taken along line C-C′ of FIG. 24. The n-side electrode 1802 is formed under the substrate 1108, a buffer layer 1208, an n-side semi-conductor layer 1308, an active layer 1408 and the p-side semiconductor layer 1508 are formed on the substrate 1108, and the light transmitting electrode 1602 and the p-side arm electrodes 1720 are formed thereon. The trenches 1014 are formed by etching the p-side semiconductor layer 1508, the active layer 1408 and the n-side semi-conductor layer 1308, and protrusions 1024 are formed on the bottom surfaces of the trenches 1014.

Identically to the semiconductor light emitting device of FIG. 20, in the semi-conductor light emitting device of FIG. 24, the trenches 1014 are designed to increase a current density below 50%.

FIG. 26 is a view showing the principle of the present invention. A light emitting region is formed almost on the whole surface of the III-nitride semiconductor light emitting device, and a temperature rise restricting unit 110 is formed by removing part of a light transmitting electrode 601, thereby restricting current flows at the center of the device.

In the case of a general high output nitride semiconductor light emitting device, when a temperature rises at the center of the device, reliability is sharply reduced in a high current operation. However, in accordance with the present invention, heat generation is basically prevented at the center of the device, and thus heat distribution is uniformized in the device.

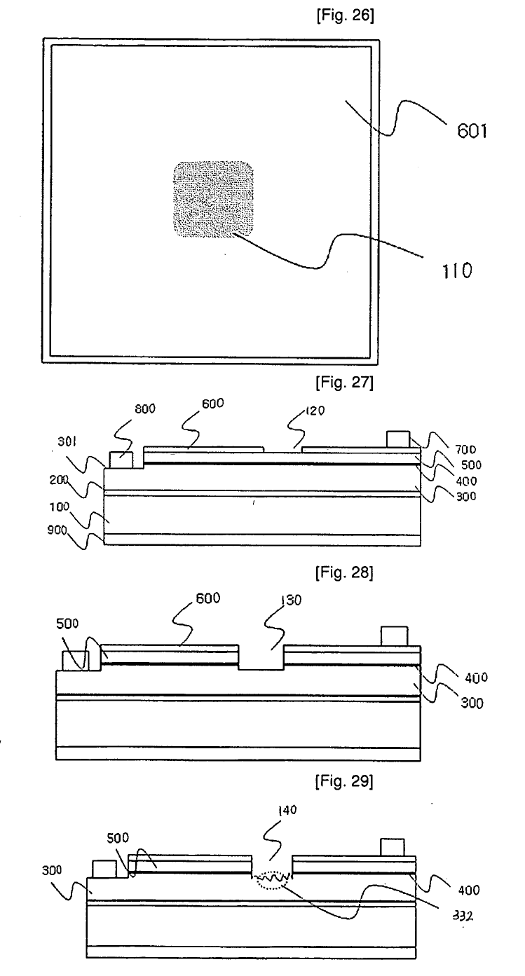

FIGS. 27 to 29 are views illustrating examples of a III-nitride semiconductor light emitting device in accordance with the present invention. The III-nitride semi-conductor light emitting device includes a substrate 100, a buffer layer 200 epitaxially grown on the substrate 100, an n-type nitride semiconductor layer 300 epitaxially grown on the buffer layer 200, an active layer 400 epitaxially grown on the n-type nitride semiconductor layer 300, a p-type nitride semiconductor layer 500 epitaxially grown on the active layer 400, a light transmitting electrode 600 formed almost on the whole surface of the p-type nitride semiconductor layer 500, a p-side electrode 700 formed on the light transmitting electrode 600, and an n-side electrode 800 formed on the n-type nitride semiconductor layer 301 exposed by mesa-etching at least the p-type nitride semiconductor layer 500 and the active layer 400. Preferably, a metal film 900 is deposited under the substrate 100 to facilitate heat emission.

In FIG. 27, a temperature rise restricting unit 120 is formed by removing the light transmitting electrode 600 at the center of the III-nitride semiconductor light emitting device, thereby restricting current flows from the center of the device to the p-type nitride semiconductor layer 500, the active layer 400 and the n-type nitride semi-conductor layer 300. As a result, heat generation is restricted at the center of the device.

In FIG. 28, a temperature rise restricting unit 130 is formed by removing the light transmitting electrode 600, the p-type nitride semiconductor layer 500, the active layer 400 and part of the n-type nitride semiconductor layer 300 at the center of the III-nitride semiconductor light emitting device, thereby basically removing current flows at the center and preventing heat generation.

In FIG. 29, a temperature rise restricting unit 140 having protrusions 332 for efficiently externally emitting (scattering) light generated on the active layer 400 on its exposed bottom surface is formed by removing the light transmitting electrode 600, the p-type nitride semiconductor layer 500, the active layer 400 and part of the n-type nitride semiconductor layer 300 from the center of the III-nitride semiconductor light emitting device, thereby preventing heat generation at the center of the device and efficiently externally emitting light through the protrusions 332.

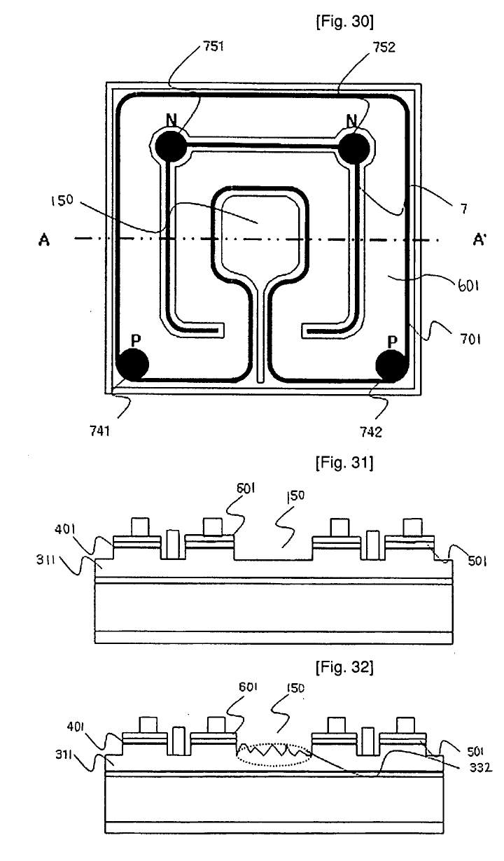

FIG. 30 is a view illustrating another example of the III-nitride semiconductor light emitting device in accordance with the present invention. A temperature rise restricting unit 150 is formed at the center of the device. A p-side electrode 701 surrounds most of edges of a light transmitting electrode 601, and also surrounds the temperature rise restricting unit 150 at the center of the device. An n-side electrode 702 is positioned between the edge-side p-side electrode 701 and the temperature rise restricting unit-side p-side electrode 701 (to surround the temperature rise restricting unit-side p-side electrode 701). The p-side electrode 701 has bonding pads 741 and 742 at the two edges of the light emitting device, and the n-side electrode 702 has bonding pads 751 and 752 at the opposite sides to the bonding pads 741 and 742 of the p-side electrode 701.

Both electrodes 701 and 702 maintain almost a constant distance to prevent partial current concentration. The positions of the n-side electrode 702 and the p-side electrode 701 can be exchanged. The area of the temperature rise restricting unit 150 is varied by the whole size of the device, preferably, decided between 10□² and 1 mm². When the area of the temperature rise restricting unit 150 is below 10□², heat generated in the device is not efficiently removed, and thus the lifespan of the device may be reduced. When the area of the temperature rise restricting unit 150 is over 1 mm², a light emitting area of the device is reduced, and thus light emitting efficiency thereof may be reduced. In addition, the temperature rise restricting unit 150 can be formed in various shapes such as circle, ellipse, triangle, tetragon and hexagon and the like.

FIG. 31 is a cross-sectional view taken along line A-A′ of FIG. 30. The temperature rise restricting unit 150 is formed by removing a light transmitting electrode 601, a p-type nitride semiconductor layer 501, an active layer 401 and part of an n-type nitride semiconductor layer 311 at the center of the device, thereby basically removing current flows at the center and preventing heat generation.

FIG. 32 is another cross-sectional view taken along line A-A′ of FIG. 30. The temperature rise restricting unit 150 is formed by removing the light transmitting electrode 601, the p-type nitride semiconductor layer 501, the active layer 401 and part of the n-type nitride semiconductor layer 311 from at center of the device, for preventing heat generation. Also, protrusions 332 are formed on the surface of the temperature rise restricting unit 150, for efficiently extracting light kept in the device. The protrusions 332 can have predetermined patterns made by a photolithography process, or atypical shapes made by wet or dry etching.

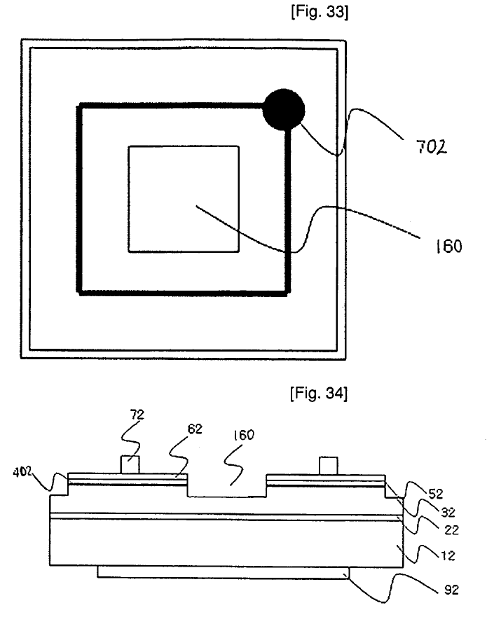

FIGS. 33 and 34 are a plane view and a cross-sectional view illustrating yet another example of the III-nitride semiconductor light emitting device in accordance with the present invention. A temperature rise restricting unit 160 is applied to a conductive substrate 12. A buffer layer 22, an n-type nitride semiconductor layer 32, an active layer 402 and a p-type nitride semiconductor layer 52 are sequentially epitaxially grown on the conductive substrate 12. A light transmitting electrode 62 is formed on a p-type nitride semiconductor layer 52, a p-side electrode 72 is formed on the light transmitting electrode 62, and an n-side electrode 92 is formed under the conductive layer 12 having an n type.

The light transmitting electrode 62, the p-type nitride semiconductor layer 52, the active layer 402 and part of the n-type nitride semiconductor layer 32 are removed at the center of the device, thereby basically removing current flows at the center and preventing heat generation. It is also preferable to form the temperature rise restricting unit of FIG. 27 or 29.

The temperature rise restricting unit 120 of FIG. 27 can be formed by masking in the process of depositing the light transmitting electrode 600, the temperature rise restricting unit 130 of FIG. 28 can be formed by dry or wet etching, and the temperature rise restricting unit 140 of FIG. 29 having the protrusions 332 can be formed by dry or wet etching.

Although the preferred embodiments of the present invention have been described, it is understood that the present invention should not be limited to these preferred embodiments but various changes and modifications can be made by one skilled in the art within the spirit and scope of the present invention as hereinafter claimed.

1. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a first array including a trench having a first inclination angle, and a second array including a trench having a second inclination angle different from the first inclination angle.

2. The semiconductor light emitting device of claim 1, wherein the first and second arrays are disposed so that a current flow can be formed in a zigzag shape therebetween.

3. The semiconductor light emitting device of claim 1, wherein the first and second arrays do not overlap with each other.

4. The semiconductor light emitting device of claim 2, wherein the first and second arrays do not overlap with each other.

5. The semiconductor light emitting device of claim 1, wherein the trench having the first inclination angle and the trench having the second inclination angle are formed by removing the structure from the region of the second semiconductor layer at least to the active layer.

6. The semiconductor light emitting device of claim 1, wherein the trench having the first inclination angle has a first length in a first direction and a second length in a second direction perpendicular to the first direction, and the first length is longer than the second length.

7. The semiconductor light emitting device of claim 1, wherein a difference between the first inclination angle and the second inclination angle is larger than a critical angle of a semiconductor material composing the semiconductor light emitting device and an external material.

8. The semiconductor light emitting device of claim 1, wherein a difference between the first inclination angle and the second inclination angle is 90°.

9. The semiconductor light emitting device of claim 1, wherein the trench having the first inclination angle includes a rough surface.

10. The semiconductor light emitting device of claim 9, wherein the trench having the first inclination angle comprises a rough surface on its sidewall.

11. The semiconductor light emitting device of claim 1, wherein the sidewall of the trench having the first inclination angle is inclined.

12. The semiconductor light emitting device of claim 1, wherein the first semi-conductor layer is a III-nitride semiconductor.

13. The semiconductor light emitting device of claim 1, wherein the second semi-conductor layer is a III-nitride semiconductor.

14. The semiconductor light emitting device of claim 1, comprising a substrate positioned under the first semiconductor layer, wherein the substrate is a conductive substrate.

15. The semiconductor light emitting device of claim 1, wherein the trench having the first inclination angle is provided with an insulator.

16. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a trench having a first length in a first direction and a second length in a second direction perpendicular to the first direction, the first length being longer than the second length, the second direction being inclined to one side of the semi-conductor light emitting device.

17. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
an array composed of a plurality of trenches including a trench having a first length in a first direction and a second length in a second direction perpendicular to the first direction, the first length being longer than the second length, the second direction being inclined to one side of the semiconductor light emitting device.

18. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a first array including a first trench and a second array including a second trench, the first and second arrays being disposed so that a current flow can be formed in a zigzag shape therebetween.

19. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a first array including a first trench and a second array including a second trench, the first and second trenches being disposed so that a current flow between the first and the second arrays can be formed in a zigzag shape.

20. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a trench formed by removing the structure from the region of the second semi-conductor layer at least to the active layer, the trench having a surface for externally emitting some of incident light from the device, scattering the other of incident light from the device back into the device, and guiding a current flow in a zigzag shape in the device.

21. The semiconductor light emitting device of claim 19, wherein the surface of the trench comprises a rough surface.

22. A semiconductor light emitting device including an active layer for generating light by recombination of electron and hole between a first semiconductor layer having a first conductivity and a second semiconductor layer having a second conductivity different from the first conductivity, the second semiconductor layer being disposed on the active layer, comprising;
a plurality of trenches having a first length in a first direction and a second length in a second direction perpendicular to the first direction, the first length being longer than the second length; and a light emitting point for omnidirectionally emitting light from the surface parallel to the active layer,
wherein the plurality of trenches are arranged to meet the whole light omnidirectionally emitted from the light emitting point.

23. A semiconductor light emitting device including a plurality of semiconductor layers having an active layer for generating light by recombination of electron and hole, the plurality of semiconductor layers being comprised of a first semi-conductor layer being positioned under the active layer and having a first conductivity and a second semiconductor layer being positioned over the active layer and having a second conductivity different from the first conductivity, comprising;
a trench formed in the plurality of semiconductor layers by removing at least the second semiconductor layer and the active layer;
a protrusion formed on the bottom surface of the trench for scattering light generated on the active layer being.

24. The semiconductor light emitting device of claim 23, wherein a side of the trench is inclined surface.

25. The semiconductor light emitting device of claim 23, wherein the first semi-conductor layer and the second semiconductor layer are comprised of AlₓGa_{y}In_{1-x-y}N (0≦x≦1, 0≦y≦1, 0≦x+y≦1).

26. The semiconductor light emitting device of claim 23, wherein the trench comprises a center trench positioned at the center of the device for restricting heat generation of the device.

27. The semiconductor light emitting device of claim 26, wherein the area of the center trench ranges from 10□² to 1 mm².

28. The semiconductor light emitting device of claim 23, wherein the plurality of semiconductor layers are formed on the substrate.

29. The semiconductor light emitting device of claim 28, wherein the substrate is a conductive substrate.

30. The semiconductor light emitting device of claim 28, wherein the substrate is a sapphire substrate.

31. The semiconductor light emitting device of claim 23, comprising;
a first electrode electrically connected to the first semiconductor layer;
and a second electrode electrically connected to the second semiconductor layer.

32. The semiconductor light emitting device of claim 31, wherein the second electrode comprises a light transmitting electrode, and a bonding pad formed on the light transmitting electrode.

33. The semiconductor light emitting device of claim 32, wherein the second electrode further comprises an arm electrode extending from the bonding pad.

34. The semiconductor light emitting device of claim 31, wherein the first semi-conductor layer is exposed by removing the plurality of semiconductor layers, and the first electrode is formed on the exposed first semiconductor layer.

35. The semiconductor light emitting device of claim 34, wherein the first electrode comprises an electrode for wire bonding, and an arm electrode extending from the electrode.

36. The semiconductor light emitting device of claim 35, wherein an edge of the first semiconductor layer is exposed by removing the plurality of semiconductor layers, and the first electrode is extending along the exposed edge of the first semiconductor layer.

37. The semiconductor light emitting device of claim 29, wherein the first electrode is formed under the substrate.

38. The semiconductor light emitting device of claim 23, wherein an edge of the first semiconductor layer is exposed by removing the plurality of semiconductor layers, and a protrusion is formed on the exposed first semiconductor layer.

39. The semiconductor light emitting device of claim 34, wherein the process for removing the plurality of semiconductor layers to form the trench, the protrusion and the first electrode is carried out by using one mask pattern.

40. The semiconductor light emitting device of claim 23, wherein the trench is formed to prevent the current flow from being blocked.

41. A semiconductor light emitting device including a plurality of semiconductor layers having an active layer for generating light by recombination of electron and hole, the plurality of semiconductor layers being comprised of a first semi-conductor layer being positioned under the active layer and having a first conductivity and a second semiconductor layer being positioned over the active layer and having a second conductivity different from the first conductivity, comprising;
a trench formed in the plurality of semiconductor layers by removing at least the second semiconductor layer and the active layer, the trench being disposed to prevent a current flow from being blocked.

42. The semiconductor light emitting device of claim 41, wherein the trench is formed in a direction of an electric field.

43. The semiconductor light emitting device of claim 41, wherein protrusion for scattering light generated in the active layer is formed on the bottom surface of the trench.

44. The semiconductor light emitting device of claim 41, wherein the first semi-conductor layer and the second semiconductor layer are comprised of AlₓGa_{y}In_{1-x-y}N (0≦x≦1, 0≦y≦1, 0≦x+y≦1).

45. A III-nitride semiconductor light emitting device, including;
a substrate, and a plurality of nitride semiconductor layers grown over the substrate, the plurality of nitride semiconductor layers having a first nitride semi-conductor layer electrically contacting a first electrode, a second nitride semi-conductor layer electrically contacting a second electrode, and an active layer positioned between the first nitride semiconductor layer and the second nitride semiconductor layer, for generating light by recombination of electron and hole, comprising;
a temperature rise restricting area being formed at the center of the device.

46. The III-nitride semiconductor light emitting device of claim 45, wherein the temperature rise restricting area is formed by removing the second electrode at the center of the device.

47. The III-nitride semiconductor light emitting device of claim 45, wherein the temperature rise restricting area is formed by removing the structure at least to the active layer at the center of the device.

48. The III-nitride semiconductor light emitting device of claim 47, wherein the temperature rise restricting area includes a protrusion at the bottom surface of the removed temperature rise restricting area.

49. The III-nitride semiconductor light emitting device of claim 45, wherein a third electrode is formed on the second electrode to surround most of the edges of the second electrode and extending toward the center of the device to surround the temperature rise restricting area.

50. The III-nitride semiconductor light emitting device of claim 49, wherein the first electrode is formed to surround the temperature rise restricting area side third electrode.

51. The III-nitride semiconductor light emitting device of claim 45, wherein the first electrode surrounds most of the edge of the device, and extends towards the center of the device and then also surrounds the temperature rise restricting area.

52. The III-nitride semiconductor light emitting device of claim 51, wherein a third electrode is formed on the second electrode to surround the temperature rise restricting area side first electrode.

53. The III-nitride semiconductor light emitting device of claim 45, wherein the substrate is a conductive substrate.

54. The III-nitride semiconductor light emitting device of claim 49, wherein two bonding pads are formed on the third electrode and positioned at the adjacent corner of the device.

55. The III-nitride semiconductor light emitting device of claim 49, wherein two bonding pads are formed on the first electrode, and positioned at the opposite side to the two bonding pads formed on the third electrode as a basis of the temperature rise restricting area.

56. The III-nitride semiconductor light emitting device of claim 45, wherein the area of the temperature rise restricting area has a dimension ranging from 10□² to 1 mm².
